(19) United States
(12) Patent Application Publication
(10) Pub. No.: US 2018/0092240 A1
(43) Pub. Date: Mar. 29, 2018

(54) CONTROL UNIT

(71) Applicant: Robert Bosch GmbH, Stuttgart (DE)

(72) Inventors: Martin Rojahn, Tuebingen (DE); Matthias Ludwig, Moessingen (DE); Michael Hortig, Eningen U. A. (DE); Thomas Schrimpf, Reutlingen (DE)

(21) Appl. No.: 15/564,550

(22) PCT Filed: Mar. 23, 2016
(86) PCT No.: PCT/EP2016/056392

§ 371 Date: Oct. 5, 2017

(30) Foreign Application Priority Data
Apr. 10, 2015 (DE) 10 2015 206 482.4

(51) Int. Cl. H05K 7/20; H05K 7/14; H05K 5/00; H05K 1/18; G01D 11/10; G01D 11/24

(52) U.S. Cl. CPC H05K 7/2039; H05K 7/1427; H05K 5/0017; H05K 2201/10151; H05K 1/18; G01D 11/10; G01D 11/245; H05K 5/0008

(57) ABSTRACT

The invention relates to a control unit (10; 10a to 10d) having a housing (13), which consists of at least two housing elements (11, 12; 61, 65, 72; 75), and having at least two circuit carriers (16; 16a, 17; 17a; 64; 81, 82), wherein the first circuit carrier (16; 16a; 64; 81) is designed for accommodating at least one heat-generating component (1) and the second circuit carrier (17; 17a; 82) is designed for accommodating at least one sensor element (40, 41), wherein the two circuit carriers (16; 16a, 17; 17a; 64; 81, 82) are connected electrically to one another, and wherein the second circuit carrier (17; 17a; 82) is provided with vibration-damping means (45; 53, 54; 85), which serve to reduce vibrations transmitted to the second circuit carrier (17; 17a; 82) via the housing (13).

### BACKGROUND OF THE INVENTION

The invention relates to a control unit such as is used in motor vehicle technology. In particular, the invention relates to a control unit for vehicle navigation or for automated driving. A control unit of said type has not only electrical and/or electronic circuit components but additionally at least one sensor which, in conjunction with a satellite navigation system, serves for determining the position of the control unit or of the vehicle. Such a sensor may for example be in the form of a pressure or magnetic field sensor, and utilizes the knowledge that the accuracy of the determination of the position or vector of an object by means of satellite-based navigation alone does not offer sufficient accuracy for many applications. Navigation solely with the aid of rate-of-rotation and/or acceleration sensors arranged in the vehicle or in the control unit, without the satellite-based navigation or satellite-based information, is equally ineffective in achieving the desired objective. Specifically in the case of automated driving, however, accurate determination of the position of the vehicle is extremely important under all circumstances.

A control unit of said type thus serves for processing both satellite-based and sensor-based information. Furthermore, a control unit of said type commonly has a first circuit carrier for the electrical and/or electronic components and a second circuit carrier for accommodating the at least one sensor, wherein the two circuit carriers are formed as a single circuit board or are formed as two separate circuit boards in order to form the two circuit carriers. It is essential here that vibrations or shocks that are transmitted via the housing of the control unit in the direction of the circuit carrier for the sensor element can lead to a functional impairment of the sensor element, which is manifest for example in a false measurement signal. Furthermore, it is commonly the case that at least one of the electrical and/or electronic components on the circuit carrier generates heat, which must likewise be dissipated to the outside in order to improve or ensure the functionality of the control unit or of the sensor. The known control units are not designed optimally in respect of the above criteria, in particular if it is sought to achieve the low manufacturing costs per control unit that are desired in the case of large unit quantities.

### SUMMARY OF THE INVENTION

Taking the presented prior art as a starting point, it is the object of the invention to design a control unit for vehicle navigation or for automated driving such that, allowing for relatively low manufacturing costs, improved functionality of the at least one sensor element in the control unit is made possible.

Said object is achieved according to the invention, substantially in that the at least one sensor element is arranged on a second circuit carrier, wherein the circuit carrier for the at least one sensor element and the circuit carrier for the at least one heat-generating component are at least indirectly electrically connected to one another, and wherein the second circuit carrier with the at least one sensor element is equipped with means for vibration damping, which means serve for reducing vibrations transmitted via the housing to the second circuit carrier.

In other words, this means that, by means of the arrangement of the at least one heat-generating component and of the at least one sensor element on different circuit carriers with the simultaneous provision of vibration damping means for the second circuit carrier on which the at least one sensor is arranged, the functionality of the sensor is improved such that a transmission of vibrations from the housing to the at least one sensor element is reduced or prevented. In particular, by contrast to the prior art, in which the at least one sensor element and the at least one heat-generating component are arranged on a single circuit board, mechanical decoupling of the two circuit carriers is realized. This is important substantially because, in the case of the prior art with a single circuit board, for the dissipation of the heat of the at least one heat-generating component, the circuit board is commonly connected in a more or less mechanically rigid manner to a heat-conducting element and to the housing. In this way, in the prior art, corresponding vibrations introduced via the housing are transmitted virtually unfiltered to the at least one sensor element.

In a first design embodiment, which makes it possible to realize a control unit of particularly compact construction, it is proposed that the two circuit carriers are formed by subregions of a common circuit board, and that, in order to form the second circuit carrier and in order to reduce vibrations transmitted via the housing to the second circuit carrier, the second circuit carrier is arranged so as to be separated, in regions, by means of cutouts, from that region of the circuit board which forms the first circuit carrier. In practice, this means that the two circuit carriers, which are formed by one and the same circuit board and which thus lie in a common plane and thereby make it possible to realize the control unit of particularly compact construction, are separated from one another for example by slot-shaped cutouts or milled-out portions, other than in a connecting region. In this way, mechanical decoupling of the two circuit carriers, or a shift of excitation frequencies from the first circuit carrier to the second circuit carrier, is achieved. In particular, such a shift of frequencies leads to a reduction of the vibration loading of the at least one sensor element arranged on the second circuit carrier.

In an alternative embodiment, which is preferred with regard to ensuring the functionality of the at least one sensor element, it is however provided that the two circuit carriers are formed by in each case one separate circuit board. In this way, complete physical separation of the two circuit carriers is made possible. In particular, it is thereby possible for the circuit carrier which bears the at least one heat-generating component to be optimized with regard to the dissipation of heat, and/or to be connected rigidly to the housing, whereas the circuit carrier which bears the at least one sensor element can be optimized with regard to its vibration damping. Here, it is in particular advantageous if all heat-generating components are arranged on the corresponding circuit carrier and all sensor elements are arranged on the other circuit carrier.

An optimization of the mechanical decoupling between the two circuit carriers or circuit boards is achieved if the first circuit carrier is connected to connector elements for the electrical contacting of the control unit, wherein the second circuit carrier is electrically connected exclusively to the first circuit carrier. This means that the circuit carrier which bears the at least one sensor element is connected to the housing only indirectly, and in particular not via connector elements in the housing region via which, for example, signals are transmitted in or transmitted out. There is thus no direct mechanical coupling of the circuit carrier which bears the at least one sensor element to the electrical connector elements of the control unit.

In a refinement of the latter proposal, it is provided that the electrical connection between the two circuit carriers is formed as a mechanically floating connection. In this way, additional and/or improved vibration decoupling between the two circuit carriers or circuit boards is achieved.

In an embodiment which is preferred from a manufacturing aspect, in the case of two circuit boards being used for the two circuit carriers, it is provided that the circuit board that forms the first circuit carrier is connected to a first housing element, in particular a housing baseplate, which serves for the fastening of the control unit to a carrier element, and that the circuit board that forms the second circuit carrier is connected to the second housing element or to another housing element.

In a further preferred embodiment of the control unit from a manufacturing aspect, which firstly permits a customer-specific arrangement and design of electrical connector elements for the control unit in a particularly simple manner, and furthermore permits a further decoupling of the circuit carrier from the housing, it is proposed that the connector elements for the electrical contacting of the control unit are arranged on a plug connector body, wherein the plug connector body is connected to a housing element, and wherein the plug connector body is mechanically decoupled with respect to the housing element. Such mechanical decoupling of the plug connector body may be realized for example by means of different materials for the plug connector body and the housing element, or by means of additional vibration-damping elements such as seals or the like, which are arranged between the plug connector body and the housing element.

For improved dissipation of the heat of the at least one heat-generating component, it is proposed that the first circuit carrier is connected, preferably in the region of the at least one heat-generating component, to at least one metallic heat-conducting element. In the simplest case, such a heat-conducting element consists for example in a housing element, for example in a housing base composed of metal, which is in particular designed for being fastened to a carrier element for the control unit, for example to a body part of a motor vehicle.

It is however alternatively it also possible for the heat-conducting element to be arranged, preferably by insert molding, in a housing element composed of plastic. Such an embodiment firstly permits a relatively low weight of the housing of the control unit and, furthermore, by means of the connection of plastic, possibly further improved vibration characteristics of the housing, that is to say a reduction of vibrations transmitted via the housing to the second circuit carrier, which bears the at least one sensor element.

Both for weight-saving reasons and for reasons relating to a design which is as inexpensive as possible and as advantageous as possible from a manufacturing aspect, it is provided that at least one of the housing elements is composed of plastic. Such a housing element is formed in particular as an injection-molded part.

### BRIEF DESCRIPTION OF THE DRAWINGS

Further advantages, features and details of the invention will emerge from the following description of preferred exemplary embodiments and from the drawing.

In the drawing:

FIG. 1 shows the components of a first control unit in a simplified longitudinal section,

FIG. 2 shows the components of the control unit of FIG. 1 in a partially assembled state in a perspective view from below,

FIG. 3 shows the components of a second control unit in a simplified longitudinal section,

FIG. 4 shows the components of the second control unit in a perspective view from below,

FIG. 5 shows the components of a third control unit in a simplified longitudinal section,

FIG. 6 shows the components of the third control unit in a perspective view from above,

FIG. 7 shows the components of a fourth control unit in a simplified longitudinal section, and

FIG. 8 shows the components of a fourth control unit in a longitudinal section.

Identical elements or elements of identical function are denoted by the same reference designations in the figures.

### DETAILED DESCRIPTION

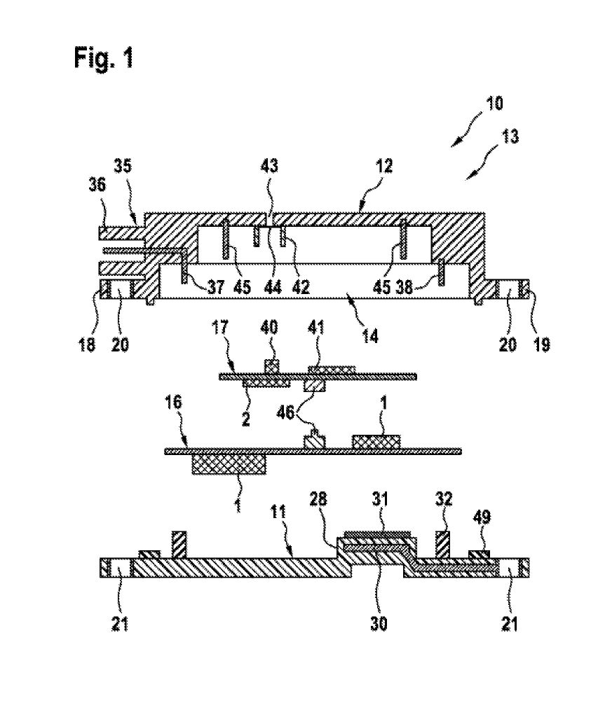

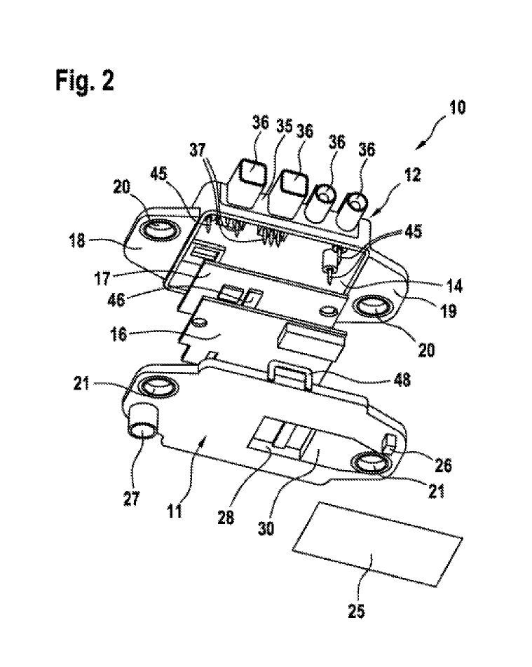

FIGS. 1 and 2 illustrate the components of a first control unit 10. The control unit 10 is used in particular as a constituent part of a navigation system or of a system for determining the location of the control unit 10 in a motor vehicle (not illustrated). Here, the control unit 10 processes both signals which are fed to the control unit 10 as input variables via a (high-frequency) antenna cable (not illustrated) and signals from sensors arranged within the control unit 10, for example pressure sensors, yaw rate sensors, magnetic field sensors or the like.

The first control unit 10 has a housing 13 composed of two housing elements 11, 12. The housing element 11 forms a housing base, whereas the housing element 12 is formed in the manner of a lid or cover and, when connected to the housing element 11, forms an interior space 14 for accommodating two separate circuit carriers 16, 17, which are for example in the form of circuit boards. The housing element 12 has two fastening sections 18, 19 which project in the manner of flanges and which have passage openings 20 formed therein. The passage openings 20 are, in the assembled state of the two housing elements 11, 12, arranged so as to overlap passage openings 21 on the housing element 11. By means of fastening elements which are not illustrated, in particular by means of fastening screws, the housing 13 can be fastened to a carrier element 25 which is illustrated merely symbolically and in a subregion, for example to a metallic body part.

For the correct positioning of the housing 13 with respect to the carrier element 25, the housing element 11 may have, on the underside averted from the housing element 12, two pin-like positioning elements 26, 27 which have different cross sections (FIG. 2) and which interact with corresponding openings on the carrier element 25 (not illustrated).

The housing element 11 is composed of plastic and is preferably formed as an injection-molded part. Said housing element has an elevation 28, in the region of which the housing element 11 projects further into the interior space 14 than in the other regions of the housing element 11. It can also be seen that a heat-conducting element 30 composed of metal is arranged in the material of the housing element 11, which heat-conducting element is at least regionally insert-molded in the material of the housing element 11, and which heat-conducting element projects into the region of at least one passage opening 21 of the housing element 11. In FIG. 2, in order to be more clearly recognizable, the heat-conducting element 30 is illustrated in at least partially cut-away form. In particular, from the illustration of FIG. 1, it can furthermore be seen that the heat-conducting element 30 terminates flush with the top side and bottom side of the housing element 11 in the region of the passage opening 21. In this way, when the housing 13 is fastened by means of fastening screws, which are commonly composed of metal, as fastening elements, a heat flow or dissipation of heat via the heat-conducting element 30 in the direction of the carrier element 25 is made possible.

The heat-conducting element 30 interacts, via a heat-conducting adhesive 31, with the underside of the first circuit carrier 16. Electrical and/or electronic components 1 are arranged on the first circuit carrier 16, wherein at least one of the components 1 is a heat-generating component 1, the heat of which can be dissipated from the interior space 14 of the housing 13 during operation via the heat-conducting element 30. For this purpose, it is provided that the elevation 28 is arranged in that region of the first circuit carrier 16 in the region of which the heat-generating component 1 is also situated. In the installed state on the housing element 11, the first circuit carrier 16 lies on a preferably encircling, preferably elastic elevation 32, composed for example of silicone, which projects from the housing element 11 in the direction of the first circuit carrier 16.

On the second housing element 12, which is likewise composed of plastic and which is in the form of an injection-molded part, there is provided a plug connector body 35. The plug connector body 35 is formed by insert molding of electrical connector elements 36 with plastics material, wherein the connector elements 36 may be designed on a customer-specific or application-specific basis. In particular, at least one of the connector elements 36 is formed as a high-frequency connector, for example in the form of a high-frequency socket, via which a high-frequency signal is fed as an input variable to at least one of the circuit carriers 16, 17. The plug connector body 35 may, as illustrated, be formed as a component separate from the housing element 12 or else may be formed as an integral constituent part of the housing element 12. If the plug connector body 35 is an element which is separate from the housing element 12, the connection to the housing element 12 may be realized by insert molding of the plug connector body 35 with the material of the housing element 12 or else in some other way, for example by means of a (sealed-off) adhesive connection.

The connector elements 36 are designed for the contacting of the first circuit carrier 16. For this purpose, they have connector regions 37 which project in the direction of the first circuit carrier 16 and which are designed to interact with corresponding openings in the first circuit carrier 16 in order to form a press-fit connection. On the side situated opposite the connector element 36, a further connecting element 38 (FIG. 1) is shown in the housing element 12, which further connecting element likewise engages into a corresponding opening, formed in the first circuit carrier 16, so as to form an interference fit or press-fit connection and which serves for further stabilizing and/or fixing the first circuit carrier 16 in the housing element 11 in the assembled state.

The second circuit carrier 17, which is likewise in the form of a circuit board, is situated parallel and, in relation to the housing element 11, on that side of the first circuit carrier 16 which is averted from the housing element 11. The second circuit carrier 17 has, in addition to the further electrical and/or electronic components 2, which preferably generate at least substantially no heat, at least one sensor element 40, 41, which in the illustrated exemplary embodiment are arranged on that side of the second circuit carrier 17 which is averted from the first circuit carrier 16. One sensor element 40 is, by way of example, formed as a pressure sensor, and in the installed state is surrounded or enclosed in a circumferential direction by a housing wall 42 of the housing element 12. For the transmission of the outside pressure to the sensor element 40, the housing element 12 is equipped, in the region of overlap with the sensor element 40, with an opening 43, in the region of which there is arranged a pressure diaphragm 44 which permits a transmission of the outside pressure to the sensor element 40. The second circuit carrier 17 is (mechanically) connected to the housing 13 substantially only via the housing element 12. For this purpose, the housing element 12 has fastening elements 45 which project in the direction of the second circuit carrier 17 and which interact with corresponding openings in the second circuit carrier 17. It is essential here that the fastening elements 45 are formed at least indirectly as vibration-damping fastening elements 45. For this purpose, it may for example be provided that the fastening elements 45 are composed of a soft and/or elastic material, such that vibrations transmitted via the housing element 12 and/or housing 13 are transmitted in damped fashion to the circuit carrier 17 which bears the at least one sensor element 40, 41. It is alternatively also conceivable, for example, for the fastening elements 45 to be of rigid form, but for the corresponding fastening openings on the second circuit carrier 17, which interact with the fastening elements 45, to have vibration-damping characteristics, for example in the form of an elastic coating or an elastic element.

The two circuit carriers 16, 17 are connected to one another by means of an electrical plug connection 46 which permits an electrical connection between the components 2 or the sensor elements 40, 41 of the circuit carrier 17 and the components 1 of the circuit carrier 16. Here, it is essential that the plug connection 46 is in the form of a mechanically floating plug connection 46, that is to say at least substantially no vibrations are transmitted from the circuit carrier 16 to the circuit carrier 17 by the plug connection 46.

In the exemplary embodiment illustrated, the two housing elements 11, 12 of the housing 13 are connected to one another by means of a detent or clip connection 48. To ensure the sealing action between the two housing elements 11, 12, it is for example the case that the housing element 11 has an encircling seal 49 which, in the exemplary embodiment, interacts with a projection or the like which is formed so as to overlap the seal 49 on the housing element 12.

It self-evidently also falls within the scope of the invention for the two housing elements 11, 12 of the housing 13 to be connected to one another by means of some other connecting technique, for example by means of an adhesive connection, a (laser-)welded connection or the like. It is essential merely that the two housing elements 11, 12 are sealingly connected to one another.

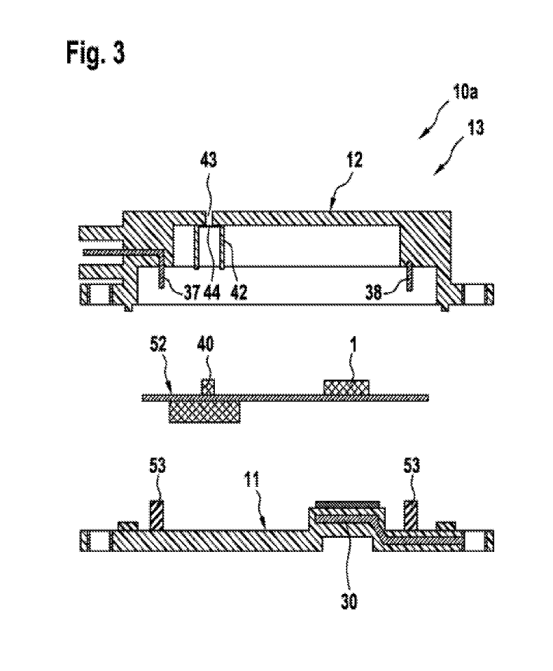

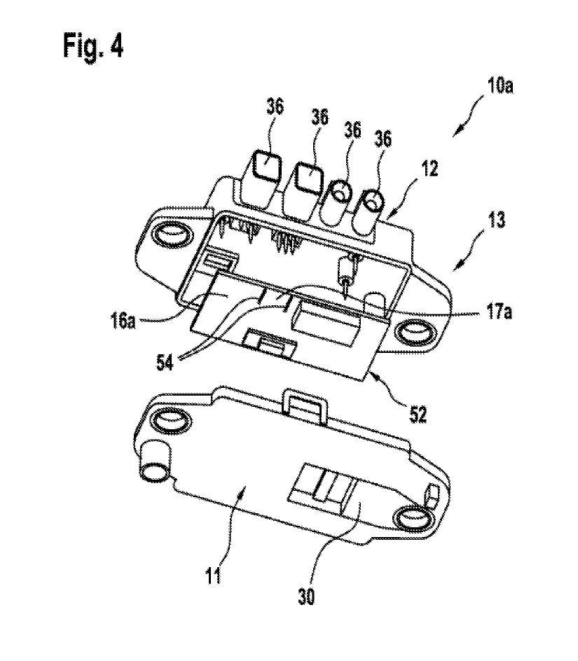

The second control unit 10a illustrated in FIGS. 3 and 4 differs from the control unit 10 in that only a single circuit board 52 is provided, which bears both the at least one heat-generating component 1 and the at least one sensor element 40. The vibration damping between the circuit board 52 and the housing 13 is realized in that the circuit board 52 is mounted by means of at least one element 53 which is arranged on the housing element 11 and which is composed of elastic material such as silicone. It may alternatively or additionally also be provided that, in order to form two circuit carriers 16a, 17a, the circuit board 52 has passage openings, slots 54 or the like in the region of the at least one sensor element 40, as is symbolically illustrated on the basis of FIG. 4, which passage openings, slots or the like separate the region in which the at least one sensor element 40 is arranged on the circuit board 52, in order to form the second circuit carrier 17a, from those regions of the circuit board 52 which form the first circuit carrier 16a with the components 1. The connection between the two circuit carriers 16a, 17a on the circuit board 52 is thus realized only in regions.

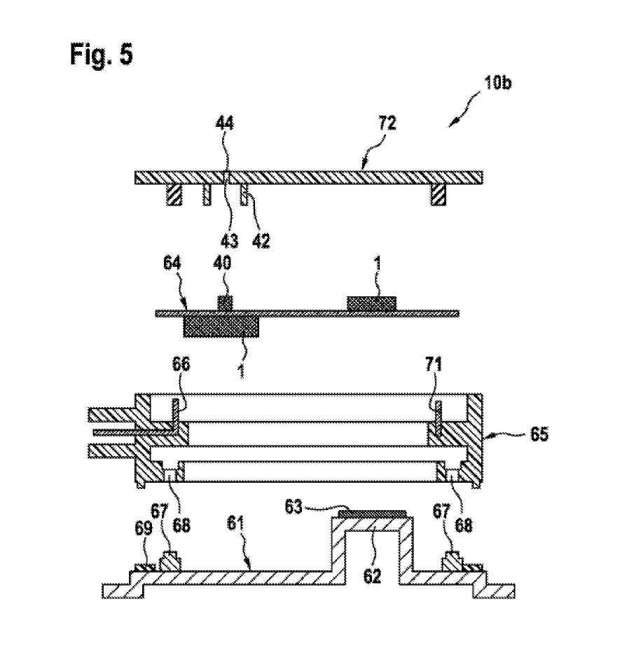

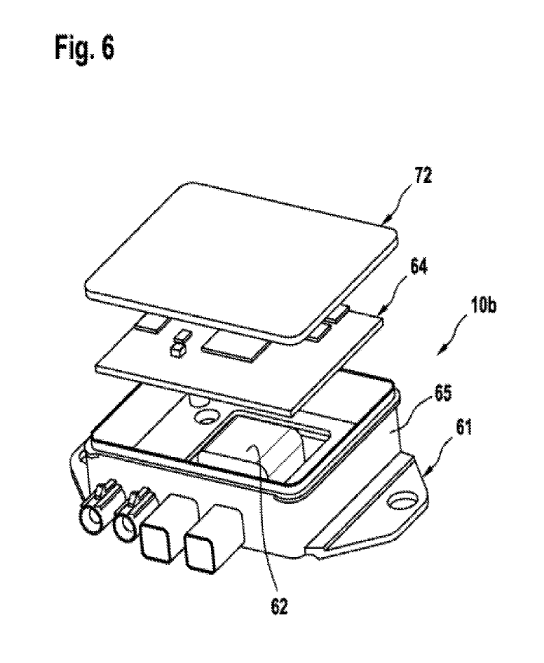

The third control unit 10b illustrated in FIGS. 5 and 6 has a first housing element 61 which is composed of metal, in particular of sheet metal, which is formed in a deep-drawing process, and which is in the form of a housing base. The first housing element 61 has an elevated region 62 which is thermally coupled by means of a heat-conducting adhesive 63 to the underside of a circuit carrier 64 which is formed as a circuit board. The housing element 61 itself therefore acts so as to dissipate heat in the direction of the carrier element 25 (not illustrated). Analogously to the circuit board 52 in the case of the second control unit 10a, both the components 1, of which at least one of the components 1 is formed as a heat-generating component 1, and at least one sensor element 40 are situated on the circuit carrier 64. In the case of the control unit 10b, too, the elevated region 62 or the heat-conducting adhesive 63 is arranged in the region of overlap with the at least one heat-generating component 1.

The first housing element 61 interacts with a frame-like or sleeve-like second housing element 65 which is composed of plastic and in which the connector elements 66 for the electrical (and mechanical) contacting of the circuit carrier 64 are also arranged. The connection between the two housing elements 61, 65 is realized by means of a detent or rivet connection, for which purpose corresponding projections 67, and openings 68 corresponding therewith, are formed on the two housing elements 61, 65. The sealing between the two housing elements 61, 65 is realized by means of a sealing element 69 arranged between the two housing elements 61, 65.

A structural unit produced from the two housing elements 61, 65 can be connected to the circuit carrier 64 by virtue of the circuit carrier 64 being designed to form a press-fit connection with the connector elements 66 and additional connection elements 71, wherein the circuit carrier 64 is inserted from above into the region of the housing element 65 in the direction of the housing element 61. Furthermore, analogously to the second control unit 10a, it may be provided that, in the region of the at least one sensor element 40, the circuit carrier 64 has measures for vibration damping in the form of corresponding cutouts or slots etc. (not illustrated), which measures reduce a transmission of vibrations via the housing elements 61, 65 to the sensor element 40.

On the side averted from the first housing element 61, the second housing element 65 can be closed off by means of a housing lid which is composed of plastic and which forms a third housing element 72. The connection between the two housing elements 64, 72 is realized, in a manner known per se, by means of an adhesive connection or a

(laser-)welded seam, for example, wherein leak-tightness between the housing elements 65, 72 is ensured by means of conventional technologies.

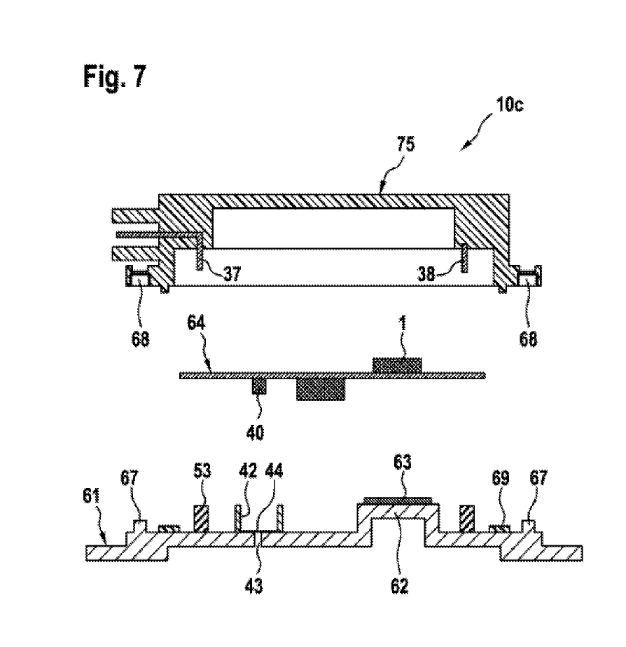

The components of the fourth control unit 10c illustrated in FIG. 7 differ from the components of the control unit 10b corresponding to FIGS. 5 and 6 substantially in that the two housing elements 65, 72 are replaced by a unipartite, lid-like or cover-like housing element 75. The housing element 75 is likewise composed of plastic and is produced by injection molding. The fourth control unit 10c is produced by virtue of the circuit carrier 64 being connected to the connector elements 66 and the connecting elements 71, which form a press-fit connection. Subsequently, the assembly composed of the circuit carrier 64 and the housing element 75 is connected to the first housing element 61 composed of metal, which in particular also permits the dissipation of heat from the at least one heat-generating thermal element 1. Furthermore, in the case of the control unit 10c, the at least one sensor element 40 is arranged on that side of the circuit carrier 64 which faces toward the housing element 61, for which purpose a corresponding opening 43 and pressure diaphragm 44 are formed in the housing element 61.

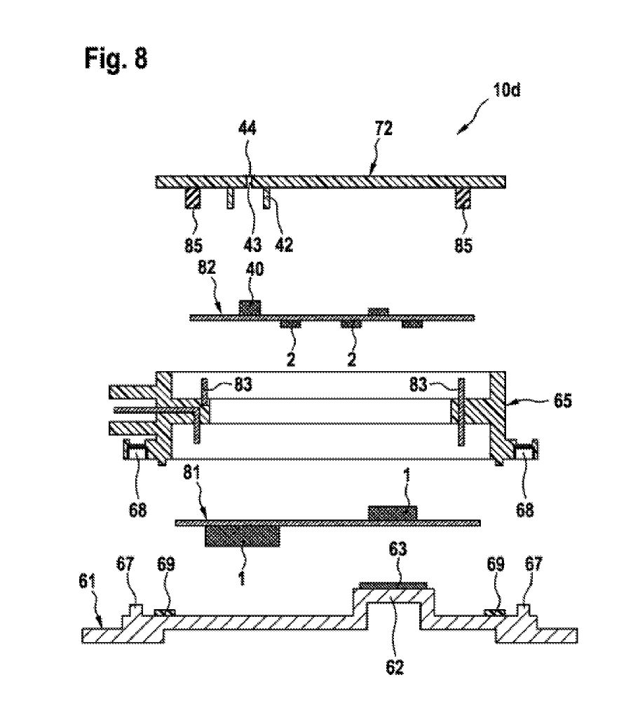

Finally, the components of a fifth control unit 10d are illustrated in FIG. 8. The construction of the fifth control unit 10d substantially corresponds to that of the third control unit 10b corresponding to FIGS. 5 and 6. By contrast to the control unit 10b, the control unit 10d has two circuit carriers 81, 82 formed as circuit boards. Whereas the first circuit carrier 81 bears the at least one heat-generating component 1, the second circuit carrier 82 bears the at least one sensor element 40. Furthermore, the second circuit carrier 82 is mechanically connected to the second housing element 65, and also electrically connected to the first circuit carrier 81, by means of pin-like connecting elements 83 which are arranged on the second housing element 65 and which form a press-fit connection. Vibration-damping elements 85, composed for example of silicone, are arranged on the lid-like third housing element 72 on the side facing toward the second circuit carrier 82, which vibration-damping elements dampen vibrations transmitted via the second housing element 65 to the second circuit carrier 82.

The control unit 10, 10a to 10d thus described may be altered or modified in a variety of ways without departing from the concept of the invention.

1. A control unit (10; 10a to 10d), having a housing (13) which is composed of at least first and second housing elements (11, 12; 61, 65, 72; 75), having at least first and second circuit carriers (16; 16a, 17; 17a; 64; 81, 82), wherein the first circuit carrier (16; 16a; 64; 81) is configured for accommodating at least one heat-generating component (1) and the second circuit carrier (17; 17a; 82) is configured for accommodating at least one sensor element (40, 41), wherein the first and second circuit carriers (16; 16a, 17; 17a; 64; 81, 82) are electrically connected to one another, and wherein the second circuit carrier (17; 17a; 82) is equipped with vibration damping means (45; 53, 54; 85) for reducing vibrations transmitted via the housing (13) to the second circuit carrier (17; 17a; 82).

2. The control unit as claimed in claim 1, characterized in that the first and second circuit carriers (16a, 17a) are formed by subregions of a common circuit board, and in that, in order to form the second circuit carrier (17a) and in order to reduce vibrations transmitted via the housing (13) to the second circuit carrier (17a), the second circuit carrier (17a) is arranged so as to be separated, in regions, by cutouts (54), from a region of the circuit board which forms the first circuit carrier (16a).

3. The control unit as claimed in claim 1, characterized in that the first and second circuit carriers (16, 17; 81, 82) are formed by in each case one separate circuit board.

4. The control unit as claimed in claim 3, characterized in that the first circuit carrier (16; 16a; 52; 64; 81) is connected to connector elements (36) for electrical contacting, and in that the second circuit carrier (17; 17a; 82) is electrically connected exclusively to the first circuit carrier (16; 16a; 81).

5. The control unit as claimed in claim 4, characterized in that the electrical connection (46; 83) between the first and second circuit carriers (16; 16a, 17; 17a; 81, 82) is formed as a mechanically floating connection.

6. The control unit as claimed in claim 3, characterized in that the circuit board that forms the first circuit carrier (16; 81) is connected to a first housing element (11; 61), which serves for fastening to a carrier element (25), and in that the circuit board that forms the second circuit carrier (17; 82) is connected to the second housing element (12) or to another housing element (65).

7. The control unit as claimed in claim 4, characterized in that the connector elements (36) for the electrical contacting are arranged on a separate plug connector body (35), and in that the plug connector body (35) is connected to the second housing element (12).

8. The control unit as claimed in claim 1, characterized in that the first circuit carrier (16; 16a; 64; 81) is thermally connected to at least one metallic heat-conducting element (30).

9. The control unit as claimed in claim 8, characterized in that the heat-conducting element (30) is arranged in a housing element (11) composed of plastic.

10. The control unit as claimed in claim 8, characterized in that the heat-conducting element is formed by a housing element (61).

11. The control unit as claimed in claim 1, characterized in that at least one of the housing elements (11, 12; 65, 72) is composed of plastic.

12. The control unit as claimed in claim 4, characterized in that at least one of the plug connector elements (36) is in the form of a high-frequency connector.

13. The control unit as claimed in claim 3, characterized in that the circuit board that forms the first circuit carrier (16; 81) is connected to a housing baseplate, which serves for fastening to a carrier element (25), and in that the circuit board that forms the second circuit carrier (17; 82) is connected to the second housing element (12) or to another housing element (65).

14. The control unit as claimed in claim 4, characterized in that the connector elements (36) for the electrical contacting are arranged on a separate plug connector body (35), and in that the plug connector body (35) is connected to the second housing element (12), wherein the plug connector body (35) is mechanically decoupled with respect to the second housing element (12).

15. The control unit as claimed in claim 1, characterized in that the first circuit carrier (16; 16a; 64; 81) is thermally connected, in a region of the at least one heat-generating component (1), to at least one metallic heat-conducting element (30).

16. The control unit as claimed in claim 8, characterized in that the heat-conducting element (30) is arranged, by insert molding, in a housing element (11) composed of plastic.
